(19) United States
(12) Patent Application Publication
(10) Pub. No.: US 2025/0357087 A1
(43) Pub. Date: Nov. 20, 2025

(54) MANUFACTURING METHOD OF INNER MEMBER OF PLASMA PROCESSING APPARATUS

(71) Applicant: Hitachi High-Tech Corporation, Minato-ku, Tokyo (JP)

(72) Inventors: Kazuhiro UEDA, Tokyo (JP); Kazuyuki IKENAGA, Tokyo (JP)

(21) Appl. No.: 18/280,354

(22) PCT Filed: Aug. 30, 2022
(86) PCT No.: PCT/JP2022/032583

§ 371 Date: Feb. 28, 2025

(51) Int. Cl. H01J 37/32; C23C 16/44

(52) U.S. Cl. CPC H01J 37/32495; C23C 16/4404; H01J 2237/334

(57) ABSTRACT

In order to provide a plasma processing apparatus or an inner member thereof, or a method of manufacturing a plasma processing apparatus or an inner member that enhances yield of a process, a processing chamber that is arranged inside a vacuum vessel, and in which plasma is formed, and a member that is arranged in the processing chamber and has a surface that faces the plasma are included, in which the member includes, on a surface thereof, a film including a material containing at least one of an yttrium oxide, an yttrium fluoride, and an yttrium oxyfluoride, and an element to be +4 valence or +6 valence ions whose ion radius is smaller than an ion radius of +3 valence yttrium ions, the film including the material containing oxygen at a molar ratio which is equal to or higher than 150% of yttrium, and fluorine at a molar ratio which is equal to or higher than 100%, preferably equal to or higher than 140%, of yttrium, on average.

### TECHNICAL FIELD

The present disclosure relates to a plasma processing apparatus that forms plasma in a processing chamber inside a vacuum vessel, and processes a processing-subject sample such as a semiconductor wafer arranged in the processing chamber, an inner member of the plasma processing apparatus, and a method of manufacturing the inner member of the plasma processing apparatus, and in particular relates to a plasma processing apparatus including a protective coating on a surface in a processing chamber that faces plasma, a member for the plasma processing apparatus or the protective coating, and a manufacturing method therefor.

### BACKGROUND ART

In steps for manufacturing a semiconductor device such as an electronic device or a magnetic memory by processing a semiconductor wafer, etching using plasma (called plasma etching) has been applied to microprocessing for forming a circuit structure on a surface of the semiconductor wafer. Such processing by plasma etching is required to achieve increasingly higher processing precision or an increasingly higher yield as the degree of integration of semiconductor devices becomes higher.

In manufacturing of semiconductor devices such as electronic devices or magnetic memories, plasma etching has been applied to microprocessing. Since the inner wall of a processing chamber of a plasma processing apparatus that performs plasma etching is exposed to a high frequency plasma and an etching gas at a time of an etching process, a film that excels in plasma resistance is formed on a surface of the inner wall to protect it. Conventionally known technologies related to materials of such plasma-resistant films include ones like those below.

JP-2004-197181-A (Patent Document 1) discloses that a material included in a film that covers a surface of a grounded portion arranged inside a plasma etching apparatus contains a Group IIIA element (at least one type selected from Sm, Eu, Gd, Tb, Dy, Ho, Er, Y, Tm, Yb, and Lu as a principal component) and a fluorine element, and contains Group IIIA fluoride phases, additionally these fluoride phases belong to an orthorhombic crystal system, and crystal phases belonging to the space group Pnma are included at a ratio equal to or higher than 50%.

JP-2009-176787-A (Patent Document 2) discloses that a film on a surface of a grounded portion arranged inside a plasma etching apparatus includes a material containing any one type or two or more types selected from Al₂O₃, YAG, Y₂O₃, Gd₂O₃, Yb₂O₃, or YF₃.

JP-2014-141390-A (Patent Document 3), JP-2016-27624-A (Patent Document 4) and JP-2018-82154-A (Patent Document 5) disclose that, as film materials of grounded portions arranged inside plasma etching apparatuses, an yttrium oxide, an yttrium fluoride, and an yttrium oxyfluoride whose average crystallite sizes are smaller than 100 nm are formed by aerosol deposition methods.

JP-2016-539250-T (Patent Document 6) discloses that a material of a film on a surface of a grounded portion of a plasma etching apparatus either contains Y₃Al₅O₁₂, Y₄Al₂O₉, Er₂O₃, Gd₂O₃, Y₂O₃, Er₃Al₅O₁₂, Gd₃Al₅O₁₂, YF₃, or Nd₂O₃ or contains Y₄Al₂O₉ and a Y₂O₃—ZrO₂ solid solution. The Y₂O₃—ZrO₂ solid solution is zirconia to which yttria is added to stabilize high-temperature crystalline phases, and is a material which is well known as yttria stabilized zirconia.

JP-2017-190475-A (Patent Document 7) discloses that crystalline structures of rare earth fluorides of Y, Sm, Eu, Gd, Er, Tm, Yb, and Lu include high-temperature types (hexagonal crystal system) and low-temperature types (orthorhombic crystal system), phase transition occur, and cracks are generated at a time of cooling from a sintering temperature, and if a very small amount of Y₂O₃ is added to an yttrium-based fluoride, for example, crystals are partially stabilized, the mode of cracks changes, and cracks on the surface are reduced.

WO 2017/043117 (Patent Document 8) discloses that an yttrium oxyfluoride is stabilized by using CaF₂.

A typical known method for reducing high-temperature crystalline phases is to perform reheating and annealing, and cause phase transition from remaining high-temperature crystalline phases to low-temperature crystalline phases. However, this method undesirably causes the growth of crystals to proceed, resulting in coarseness of crystallites. For example, although an embodiment of Patent Document 1 discloses a coating whose ratio of orthorhombic crystals is 100%, the crystal size is equal to or greater than 1 μm.

On the other hand, “Kazuhiro Ueda, Kazuyuki Ikenaga, Tomoyuki Tamura, and Masahiro Sumiya, ‘Examination of Crystalline Structure of Yttrium-Based Material for Plasma Etching Apparatuses and Particles Generation Mechanism,’ The Discussion Group of X-Ray Analysis, The Japan Society for Analytical Chemistry (edited), Advances in X-Ray Chemical Analysis 50, AGNE Gijutsu Center Inc., date of publication: Apr. 1, 2019, p. 197 to 205” (Non-Patent Document 1) discloses that generation of particles increases if an average crystallite size is increased. Furthermore, JP-2019-192701-A (Patent Document 9) discloses that generation of particles in a semiconductor wafer processed inside a plasma processing apparatus is reduced by making crystallite sizes of a film of a grounded portion arranged inside the plasma processing apparatus equal to or smaller than 50 nm, and discloses that making the temperature of a base material of the grounded portion a temperature in a predetermined range when the film is formed allows the low-temperature crystalline phase ratio to be equal to or higher than 60% and allows the crystallite sizes to be equal to or smaller than 50 nm.

In addition, “Masayuki Takashima, Gentaro Kano, and Masahiko Kawase, ‘Formation and Electrical Conductivity of Yttrium Fluoride Stabilized Zirconia,’ Denki Kagaku oyobi Kogyo Butsuri Kagaku, Vol. 53, No. 2 (1985), date of publication: Feb. 5, 1985, p. 119 to 124” (Non-Patent Document 2) discloses an academic research related to yttrium fluoride stabilized zirconia (YF₃—ZrO₂).

That is, since crystalline phase changes from high-temperature crystalline phases to low-temperature crystalline phases do not occur at a time of plasma discharge if the high-temperature crystalline phases are stabilized at room temperature, it can be expected to prevent generation of particles attributable to the crystalline phase changes.

“Akihide Kuwabara, Yuichi Ikuhara, and Taketo Sakuma, ‘Analysis of Phase Stability in Cubic Zirconia Solid Solutions by First Principle Molecular Orbital Method,’ Journal of the Society of Materials Science, Vol. 50, No. 6 (2001), date of publication: Jun. 15, 2001, p. 619 to 624” (Non-Patent Document 3) derives, by a first principle molecular orbital method, that factors of stabilization of zirconia (ZrO₂) are a decrease of the coordination number of Zr due to the oxygen ion hole effect into which Y³⁺ ions with a valence smaller than the valence of Zr⁴⁺ ions are introduced, and lattice strain into which ions with an ion radius greater than the ion radius (80 pm) of Zr⁴⁺ are introduced.

Patent Document 8 discloses a technology in which CaF₂ is added to an yttrium oxide and an yttrium fluoride and sintered, and high-temperature crystalline phases of an yttrium oxyfluoride are stabilized or partially stabilized. This method suggests that it is possible to stabilize high-temperature crystalline phases by introducing Ca²⁺ ions with a valence smaller than the valence of Y³⁺, and using the hole effects of fluorine ions or oxygen ions.

Patent Document 7 discloses that high-temperature crystalline phases are partially stabilized, the mode of cracks changes, and cracks on a surface can be reduced by adding a very small amount of Y₂O₃ to an yttrium-based fluoride. It is not possible with the element composition including Y, O and F to stabilize high-temperature crystalline phases by the hole effect or lattice strain calculated with stabilization of zirconia. Accordingly, it is considered that Y₂O₃—YF₃ in Patent Document 7 reduces cracks due to a factor which is different from stabilization or partial stabilization of high-temperature crystalline phases.

“Masao Sato and Shunpei Fukuda, “Manufacturing of Yttrium Iron Garnet Single Crystal by YF₃—PbF₂ Melted Salt Bath,” Journal of the Ceramic Society, Vol. 71, No. 805 (1963), date of publication: 963, p. 101 to 104″ (Non-Patent Document 4) discloses 15 mol % of an yttrium oxide melts in an yttrium fluoride melt at 1260° C.

### PRIOR ART DOCUMENT

### Patent Documents

Patent Document 1: JP-2004-197181-A
Patent Document 2: JP-2009-176787-A
Patent Document 3: JP-2014-141390-A
Patent Document 4: JP-2016-27624-A
Patent Document 5: JP-2018-82154-A
Patent Document 6: JP-2016-539250-T
Patent Document 7: JP-2017-190475-A
Patent Document 8: WO 2017/043117
Patent Document 9: JP-2019-192701-A

### Non-Patent Document

Non-Patent Document 1: Kazuhiro Ueda, Kazuyuki Ikenaga, Tomoyuki Tamura, and Masahiro Sumiya, “Examination of Crystalline Structure of Yttrium-Based Material for Plasma Etching Apparatuses and Particles Generation Mechanism,” The Discussion Group of X-Ray Analysis, The Japan Society for Analytical Chemistry (edited), Advances in X-Ray Chemical Analysis 50, AGNE Gijutsu Center Inc., date of publication: Apr. 1, 2019, p. 197 to 205
Non-Patent Document 2: Masayuki Takashima, Gentaro Kano, and Masahiko Kawase, “Formation and Electrical Conductivity of Yttrium Fluoride Stabilized Zirconia,” Denki Kagaku oyobi Kogyo Butsuri Kagaku, Vol. 53, No. 2 (1985), date of publication: Feb. 5, 1985, p. 119 to
Non-Patent Document 3: Akihide Kuwabara, Yuichi Ikuhara, and Taketo Sakuma, “Analysis of Phase Stability in Cubic Zirconia Solid Solutions by First Principle Molecular Orbital Method,” Journal of the Society of Materials Science, Japan, Vol. 50, No. 6 (2001), date of publication: Jun. 15, 2001, p. 619 to 624
Non-Patent Document 4: Masao Sato and Shunpei Fukuda, “Manufacturing of Yttrium Iron Garnet Single Crystal by YF₃—PbF₂ Melted Salt Bath,” Journal of the Ceramic Society, Vol. 71, No. 805 (1963), date of publication: 1963, p. 101 to 104

### SUMMARY OF THE INVENTION

### Problem to be Solved by the Invention

However, there have been problems in the conventional technologies described above since consideration in the following respects has been inadequate.

That is, as the precision of processing required for plasma processing apparatuses used for plasma etching becomes higher, the size (e.g., the length of the diameter) of particles generated during plasma etching processes in processing chambers arranged inside vacuum vessels of the plasma processing apparatuses also has been decreasing. It has been required to suppress generation of such fine particles (particles) with smaller diameters. In addition, it has been required to continue suppressing generation of particles even in a case where the plasma processing apparatuses are continuously activated for a long period of time.

Since a coating is fluoridized by plasma processing gas in the conventional technologies described above in which a rare earth oxide is used as a film, conditions for generating a thermal spray coating that can sufficiently suppress corrosion or generation of microparticles (referred to also as particles) described above have not been considered sufficiently. In addition, since a coating is oxidized by plasma processing gas in the conventional technologies described above in which a rare earth fluoride is used, conditions for generating a thermal spray coating that can sufficiently suppress corrosion or generation of microparticles described above have not been considered sufficiently. Furthermore, regarding a rare earth oxyfluoride also, since a crystalline phase change occurs when a coating is oxidized by plasma processing gas in the conventional technologies described above, conditions for generating a thermal spray coating that can sufficiently suppress corrosion or generation of microparticles described above have not been considered sufficiently.

That is, the conventional technology described in Patent Document 8 is a technology in which CaF₂ is added to an yttrium oxide and an yttrium fluoride and sintered, and high-temperature crystalline phases of an yttrium oxyfluoride are stabilized or partially stabilized. This conventional technology suggests that it is possible to stabilize high-temperature crystalline phases by introducing Ca²⁺ ions with a valence smaller than the valence of Y³⁺, and using the hole effects of fluorine ions or oxygen ions.

Patent Document 7 discloses that high-temperature crystalline phases are partially stabilized, the mode of cracks changes, and cracks on a surface can be reduced by adding a very small amount of Y₂O₃ to an yttrium-based fluoride. It is not possible with the element composition including Y, O, and F to stabilize high-temperature crystalline phases by the hole effect or lattice strain calculated with stabilization of zirconia. Accordingly, it is considered that Y₂O₃—YF₃ in Patent Document 7 reduces cracks due to a factor which is different from stabilization or partial stabilization of high-temperature crystalline phases.

In this manner, it is considered that YF₃ or YOF is (partially) stabilized by adding Y₂O₃ and CaF₂, and generation of cracks at a time of film formation is suppressed in Patent Documents 7 and 8; however, fluoridization or oxidation occurs due to plasma processing gas, and accordingly, conditions for generating a thermal spray coating that can sufficiently suppress corrosion or generation of microparticles described above have not been considered sufficiently.

In addition, a typical method described in Patent Document 8 for reducing high-temperature crystalline phases is a method in which reheating and annealing are performed, and phase transitions from remaining high-temperature crystalline phases to low-temperature crystalline phases are caused. However, this method causes the growth of crystals to proceed, resulting in coarseness of crystallites. Although an embodiment of Patent Document 1 discloses a coating whose ratio of orthorhombic crystals is 100%, the crystal size is equal to or greater than 1 μm. On the other hand, although Patent Document 9 discloses a method in which a low-temperature crystalline phase ratio is made equal to or higher than 60%, and crystallite sizes are made equal to or smaller than 50 nm, it is difficult to realize a high low-temperature crystalline phase ratio which exceeds 70 to 80%.

Non-Patent Document 4 discloses that 15 mol % of an yttrium oxide melts in an yttrium fluoride melt at 1260° C. According to examination by the present disclosers, it has been known that YF₃ is segregated in the grain boundaries of YOF particles in a fluorine-rich YOF film. Because of this, Y₂O₃—YF₃ is decomposed to YF₃ and YOF in the end, and the molar ratio YF₃:YOF becomes 3:2. On the basis of this, it is considered that Y₂O₃—YF₃ in Patent Document 7 stops the progress of cracks due to YOF in YF₃ serving as pinning sites.

As has been explained above, contamination of processing-subject samples is caused due to generated particles (particles) in conventional technologies, and the yield of processes is impaired.

An object of the present disclosure is to provide a plasma processing apparatus or an inner member thereof, or a method of manufacturing the inner member that makes it possible to reduce generation of particles and enhance the yield of a process.

Other problems and novel features will become clear from the description and attached figures of the present specification.

### Means for Solving the Problem

A brief explanation of an overview of representative features of the present disclosure is as follows.

The object described above is attained by a plasma processing apparatus including: a processing chamber that is arranged inside a vacuum vessel, and in which plasma is formed; and a member that is arranged in the processing chamber, and has a surface that faces the plasma, in which the member includes, on a surface thereof, a film including a material containing at least one of an yttrium oxide, an yttrium fluoride, and an yttrium oxyfluoride, and an element to be +4 valence or +6 valence ions whose ion radius is smaller than an ion radius of +3 valence yttrium ions, the film including the material containing oxygen at a molar ratio which is equal to or higher than 150% of yttrium on average, and fluorine at a molar ratio which is equal to or higher than 100%, preferably equal to or higher than 140%, of yttrium on average, or is attained by the member for the plasma processing apparatus.

### Advantages of the Invention

The plasma processing apparatus or a member therefor according to the present disclosure makes it possible to reduce generation of particles from a coating on the surface of the member arranged in a processing chamber. Since contamination of processing-subject samples caused by particles is reduced thereby, the yield of processes on the processing-subject samples can be enhanced.

### BRIEF DESCRIPTION OF THE DRAWINGS

FIG. 1 is a longitudinal cross-sectional view schematically depicting an overview of a configuration of a plasma processing apparatus according to an embodiment.

FIG. 2 is a figure depicting dependence of an average size of crystallites and an amount of generated particles on plasma discharge time.

FIG. 3 is a figure depicting the dependence of the average size of crystallites, the high-temperature crystalline phase ratio and the amount of generated particles on plasma discharge time.

FIG. 4 is a figure depicting a correlation between a high-temperature crystalline phase ratio and an amount of particles generated with plasma discharge for a certain length of time.

FIG. 5 is a figure schematically depicting a manufacturing method for forming a film on the surface of a grounded electrode depicted in the embodiment in FIG. 1.

FIG. 6 is a figure depicting a relation among the compositions of yttrium oxyfluorides, an yttrium fluoride, and an yttrium oxide.

FIG. 7 is a figure depicting a table depicting comparison of characteristics among films formed according to conventional technologies and films according to the present embodiment.

### MODES FOR CARRYING OUT THE INVENTION

Hereinbelow, an embodiment of the present disclosure is explained with the figures. Note that, in the following explanation, identical reference characters are given to identical constituent elements, and repetitive explanations are omitted, in some cases. Note that, whereas the figures are drawn schematically as compared to actual modes in some cases in order to make explanations clearer, the figures depict merely examples, and do not limit interpretation of the present disclosure.

### Embodiment

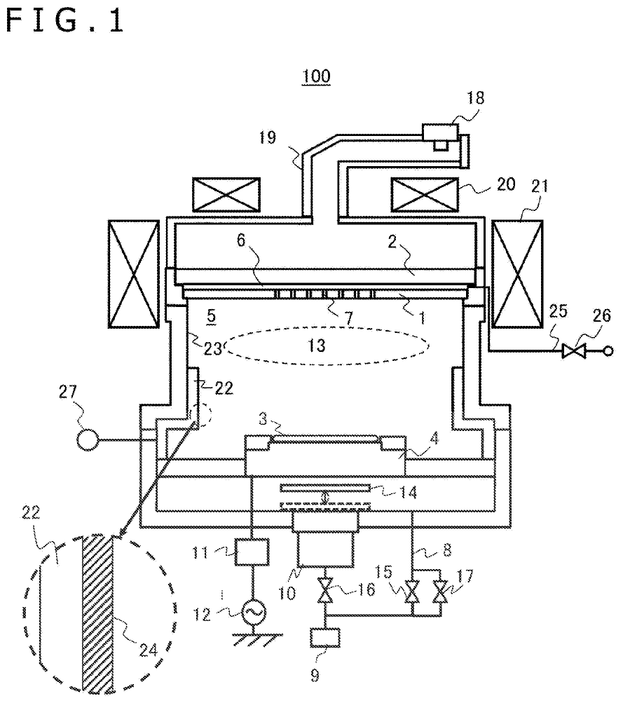

FIG. 1 is a longitudinal cross-sectional view schematically depicting an overview of a configuration of a plasma processing apparatus according to an embodiment.

A plasma processing apparatus 100 according to the present embodiment is a plasma etching apparatus, and includes: a vacuum vessel having a cylindrical portion; a plasma forming section arranged around the upper portion or circumference of the cylindrical portion to surround the upper portion or circumference; and an evacuating section that is arranged below the vacuum vessel, and includes a vacuum pump to evacuate the inside of the vacuum vessel. A processing chamber 5 which is a space where plasma is formed is arranged inside the vacuum vessel, and is formed to be capable of communicating with the evacuating section.

The upper portion of the processing chamber 5 forms a discharge chamber which is a space whose circumference is surrounded by a cylindrical inner wall, and in which plasma 13 is formed. A stage 4 is arranged inside the processing chamber 5 and below the discharge chamber where the plasma 13 is generated. The stage 4 is a sample stage on which a wafer 3 which is a processing-subject substrate is placed and retained on its top surface. For example, the plasma processing apparatus 100 can perform an etching process (hereinafter, also referred to as a process simply) on the wafer 3 which is a processing-subject substrate placed on the stage 4.

The stage 4 includes a cylindrical member whose vertical central axis is arranged concentrically with the discharge chamber when seen from above or arranged at such an appropriately approximate position that the cylindrical member can be regarded as being concentric with the discharge chamber. There is an empty space between the bottom of the processing chamber 5 where an opening communicating with the evacuating section is arranged and the bottom surface of the stage 4. The stage 4 is retained at an intermediate position in the vertical direction between the upper end surface and lower end surface of the processing chamber 5. An inner space of the processing chamber 5 below the stage 4 communicates with the discharge chamber via a gap between the side wall of the stage 4 and the cylindrical inner wall surface of the processing chamber 5 surrounding the circumference of the stage 4. This communication forms a path for discharged air where products generated on the top surface of the wafer 3 and in the discharge chamber or plasmas or gas particles in the discharge chamber pass through, and are discharged to the outside of the processing chamber 5 by the evacuating section while the wafer 3 above the top surface of the stage 4 is being processed.

The stage 4 has a base material which is a cylindrical metallic member. The base material of the stage 4 has arranged thereon: a heater (not depicted) arranged inside a dielectric film arranged to cover the top surface of the base material; and a coolant flow channel (not depicted) arranged inside the base material, concentrically around the central axis described above or helically to form layers of channels. Furthermore, in a state where the wafer 3 is placed on the top surface of the dielectric film described above of the stage 4, a heat-transferable gas such as He is supplied to a gap between the bottom surface of the wafer 3 and the top surface of the dielectric film. Because of this, a pipe (not depicted) through which the heat-transferable gas flows is arranged inside the base material and the dielectric film.

Furthermore, the base material of the stage 4 is connected, by a coaxial cable via an impedance matching device 11, with a high frequency power supply 12 that is supplied with high frequency power for forming an electric field for attracting charged particles in plasma above the top surface of the wafer 3 while the wafer 3 is being processed with the plasma. In addition, film-like electrodes (not depicted) that are supplied with direct current power for inducing, inside the dielectric film and the wafer 3, electrostatic force for attracting under suction and retaining the wafer 3 to and on the top surface of the dielectric film are provided above the heater in the dielectric film above the base material of the stage 4. The electrodes are arranged symmetrically about the vertical central axis of an approximately circular top surface of the wafer 3 or the stage 4 for each of a plurality of areas extending in a radial direction from the central axis, and are formed to be capable of giving a different polarity for each of the plurality of areas.

A window member 2 is provided above the top surface of the stage 4 in the processing chamber 5. The window member 2 is arranged to face the top surface of the stage 4 and forms the upper portion of the vacuum vessel. The window member 2 is made of a dielectric such as quartz or ceramic and has a disc shape that serves as an airtight seal between the inner side and outer side of the processing chamber 5. At a position that is below the window member 2 and forms the ceiling surface of the processing chamber 5, a shower plate 1 arranged with a clearance 6 from the bottom surface of the window member 2 is provided. The shower plate 1 is made of a dielectric such as quartz and has a disc shape including a plurality of through-holes 7 at a middle portion thereof.

The clearance 6 is coupled to the vacuum vessel such that it communicates with a process gas supply pipe 25. A valve 26 that opens or closes the inside of the process gas supply pipe 25 is arranged at a predetermined location on the process gas supply pipe 25. The flow rate or speed of a gas for processing (process gas) supplied into the processing chamber 5 is adjusted by gas-flow-rate control means (not depicted) coupled to a one-end side of the process gas supply pipe 25, and the process gas is caused to flow into the clearance 6 through the process gas supply pipe 25 opened by the valve 26. Thereafter, the process gas having flowed into the clearance 6 is diffused inside the clearance 6, and is supplied from the upper portion of the processing chamber 5 into the processing chamber 5 through the through holes 7 of the shower plate 1.

The evacuating section that discharges a gas or particles inside the processing chamber 5 is arranged at the lower portion of the vacuum vessel. The evacuating section discharges the gas or particles inside the processing chamber 5 through an evacuation port which is an opening for evacuation arranged directly below the stage 4 at the bottom of the processing chamber 7 such that its vertical central axis almost coincides with the vertical central axis of the stage 4. The evacuating section includes a pressure adjustment plate 14, and a turbomolecular pump 10 which is a vacuum pump. The pressure adjustment plate 14 is a disc-shaped valve that moves up and down above the evacuation port, and increases and decreases the area size of a flow channel through which a gas flows into the evacuation port. The evacuating section further has a dry pump 9 which is a roughing vacuum pump, and a valve 16. The outlet of the turbomolecular pump 10 is coupled to and communicates with the dry pump 9 via an evacuation pipe. The valve 16 is arranged on the evacuation pipe.

The pressure adjustment plate 14 also plays a role of a valve that opens and closes the evacuation port. A pressure sensor 27 which is a sensor for detecting the internal pressure of the processing chamber 5 is provided to the vacuum vessel. A signal output from the pressure sensor 27 is transmitted to an undepicted control section, and a pressure value is sensed. The pressure adjustment plate 14 is driven on the basis of a command signal output from the control section according to the pressure value. Thereby, the vertical position of the pressure adjustment plate 14 changes, and the area size of the evacuation flow channel described above is increased or decreased.

A valve 15 in the valve 15 and a valve 17 that are connected to an evacuation pipe 8 is a slow evacuation valve for slowly evacuating the processing chamber 5 from the atmospheric pressure to the vacuum pressure by using the dry pump 9. On the other hand, the valve 17 is a main evacuation valve for high-speed evacuation by using the dry pump 9.

A waveguide 19 and a magnetron oscillator 18 are arranged in the space around the upper portion and side wall of the cylindrical portion of the upper portion of the vacuum vessel forming the processing chamber 5. The waveguide 19 and the magnetron oscillator 18 are constituent elements for forming an electric field or a magnetic field supplied to the processing chamber 5 for forming plasma. That is, the waveguide 19 which is a line in which a microwave electric field supplied into the processing chamber 5 is propagated is arranged above the window member 2, and the magnetron oscillator 18 that oscillates and outputs the microwave electric field is arranged at one end of the waveguide 19.

The waveguide 19 includes a rectangular waveguide section and a circular waveguide section. The rectangular waveguide section has a rectangular longitudinal cross-section, and the axis of the rectangular waveguide section extends in the horizontal direction. The magnetron oscillator 18 is arranged at the one end of the rectangular waveguide section. The circular waveguide section is connected to the other end of the rectangular waveguide section, and the central axis of the circular waveguide section extends in the vertical direction. The circular waveguide section has a circular traverse cross-section. A cylindrical cavity portion with a large diameter is arranged at the lower end of the circular waveguide section. The cavity portion is formed to intensify an electric field in a particular mode therein. A solenoid coil 20 and a solenoid coil 21 at a plurality of stages which are magnetic field generating means are formed to surround the upper portion of the cavity portion and the circumference of the upper portion of the cavity portion, and furthermore to surround the lateral circumference of the processing chamber 5.

In the plasma processing apparatus 100 depicted in FIG. 1, the unprocessed wafer 3 is transferred into the processing chamber 5 by being placed on the leading end of an arm of a vacuum transfer apparatus (not depicted) such as a robot arm arranged in a transfer chamber inside a vacuum transfer container which is another vacuum vessel (not depicted) connected with the side wall of the vacuum vessel. Then, the unprocessed wafer 3 at the leading end of the arm is placed on the top surface of the stage 4. After the arm of the vacuum transfer apparatus withdraws from the processing chamber 5, the inside of the processing chamber 5 is sealed. Then, the unprocessed wafer 3 is retained on the dielectric film of the stage 4 by electrostatic force induced by application of a direct current voltage to an electrode for electrostatic suctional attraction in the dielectric film. In this state, a heat-transferable gas such as He is supplied through a pipe arranged inside the stage 4 to a gap between the bottom surface of the wafer 3 and the top surface of the dielectric film forming the top surface of the stage 4. Furthermore, a coolant whose temperature has been adjusted to a temperature in a predetermined range by an undepicted coolant temperature adjuster is supplied to the coolant flow channel inside the stage 4. Thereby, heat transfer between the wafer 3 and the base material of the stage 4 whose temperature has been adjusted is facilitated, and the temperature of the wafer 3 is adjusted to a temperature value in an appropriate range at the start of the process.

The process gas whose flow rate or speed has been adjusted by the gas-flow-rate control means passes through the process gas supply pipe 25, and is supplied into the processing chamber 5 through the through hole 7 from the clearance 6. Also, due to operation of the turbomolecular pump 10, the inside of the processing chamber 5 is evacuated through the evacuation port, and due to the balance between them (the supply of the process gas into the processing chamber 5 and the evacuation of the inside of the processing chamber 5), the internal pressure of the processing chamber 5 is adjusted to a pressure value in a range suited for the process. In this state, the microwave electric field oscillated by the magnetron oscillator 18 propagates through the inside of the waveguide 19, is transmitted through the window member 2 and the shower plate 1, and is emitted into the processing chamber 5. Furthermore, a magnetic field generated at the solenoid coils 20 and 21 is supplied to the processing chamber 5. Due to the interaction between the magnetic field and the microwave electric field, electron cyclotron resonance (ECR: Electron Cyclotron Resonance) is induced, and atoms or molecules of the process gas are excited to cause ionization or dissociation thereof, thereby generating the plasma 13 inside the processing chamber 5.

When the plasma 13 is formed, high frequency power from the high frequency power supply 12 is supplied to the base material of the stage 4, a bias potential is formed above the top surface of the wafer 3, charged particles such as ions in the plasma 13 are attracted to the top surface of the wafer 3, and an etching process on a processing-subject film layer preformed on the top surface of the wafer 3 in a film structure having a plurality of film layers including the processing-subject film layer and a mask layer proceeds along a pattern shape of the mask layer. When it is sensed by an undepicted sensor that the process on the processing-subject film layer has reached its endpoint, the supply of the high frequency power from the high frequency power supply 12 is stopped, the plasma 13 is extinguished, and the process is stopped.

When it is assessed by the control section that the etching process on the wafer 3 need not be proceeded with further, high evacuation is performed. Furthermore, after the electrostatic force is extinguished, and the suctional attraction to the wafer 3 is stopped, the arm of the vacuum transfer apparatus enters the processing chamber 5, and the processed wafer 3 is transferred to the arm. Thereafter, as the arm retracts, the wafer 3 is carried out to the vacuum transfer chamber outside the processing chamber 5.

The inner side wall surface of such a processing chamber 5 is a surface that faces the plasma 13, and is exposed to its particles. On the other hand, for stabilizing the potential of the plasma 13, which is a dielectric, a member to function as a grounded electrode that faces the plasma and contacts the plasma needs to be arranged in the processing chamber 5.

For the purpose of making a grounded electrode 22 serve a function as a grounded electrode, the plasma processing apparatus 100 is arranged to cover the surface of the lower portion of the side wall (inner side wall) inside the processing chamber 5 surrounding the discharge chamber. The grounded electrode 22 includes a ring-shaped member that is arranged to cover the surface of the lower portion of the inner side wall of the processing chamber 5 surrounding the discharge chamber, and surround the circumference of the stage 4 at the upper portion of the top surface of the stage 4. The grounded electrode 22 includes a base material including an electrically conductive material and a coating that covers the surface of the base material. In this example, the base material of the grounded electrode includes, as its base material, a metal such as a stainless alloy or an aluminum alloy.

In a case where the surface of the base material lacks a coating, the grounded electrode 22 is exposed to the plasma 13 at the location (a portion lacking the coating), and accordingly, there is a possibility that the relevant location becomes the source of corrosion or generation of particles that induces contamination of the wafer 3. Accordingly, in order to suppress contamination, a coating 24 including a highly plasma-resistant material is arranged on the surface of the grounded electrode 22 such that it covers the base material of the grounded electrode 22. The coating 24 allows suppression of damage to the grounded electrode 22 due to the plasma while maintaining the function as the electrode via the plasma of the grounded electrode 22 that covers the inner wall of the processing chamber 5. The base material of the grounded electrode 22 and the coating 24 arranged to cover the base material can be regarded as an inner member whose surface faces the plasma. The coating 24 is also referred to as a film 24 in some cases.

Note that the coating 24 may be a multilayered film. In the present embodiment, for example, the coating 24 used is a film in which many yttrium oxide crystals, yttrium fluoride crystals, and/or yttrium oxyfluoride crystals are deposited or formed integrally on the surface of the base material of the grounded electrode 22 that is given a surface roughness in a predetermined range by using atmospheric plasma spraying, suspension plasma spraying, detonation flame spraying, low pressure plasma spraying, aerosol deposition (AD: Aerosol Deposition), or physical vapor deposition (PVD: physical vapor deposition) using an yttrium oxide (Y₂O₃), an yttrium fluoride (YF₃), an yttrium oxyfluoride (YOF), or a material containing one or more of these.

On the other hand, a metallic member such as a stainless alloy or aluminum alloy is used also for a base material 23 of the inner wall of the processing chamber 5 not having a function as the grounded electrode 22. In order to suppress corrosion, metal contamination or generation of particles that is caused by exposure to the plasma 13, a process to enhance corrosion resistance against the plasma, and reduce wear of the base material 23 such as passivation treatment, various types of thermal spraying, PVD, or chemical vapor deposition is implemented also on the surface of the base material 23.

Note that, in order to reduce the interaction described above of the base material 23 with the plasma 13, a cylindrical cover (not depicted) made of a ceramic material such as an yttrium oxide or quartz may be arranged on the inner side of the inner wall surface of the cylindrical base material 23 and between the base material 23 and the discharge chamber. By such a cover being arranged between the base material 23 and the plasma 13, contact with highly reactive particles in the plasma 13 or collision of charged particles can be interrupted or reduced, and wear of the base material 23 can be suppressed.

The coating 24 according to the present embodiment is fabricated on the basis of the following findings.

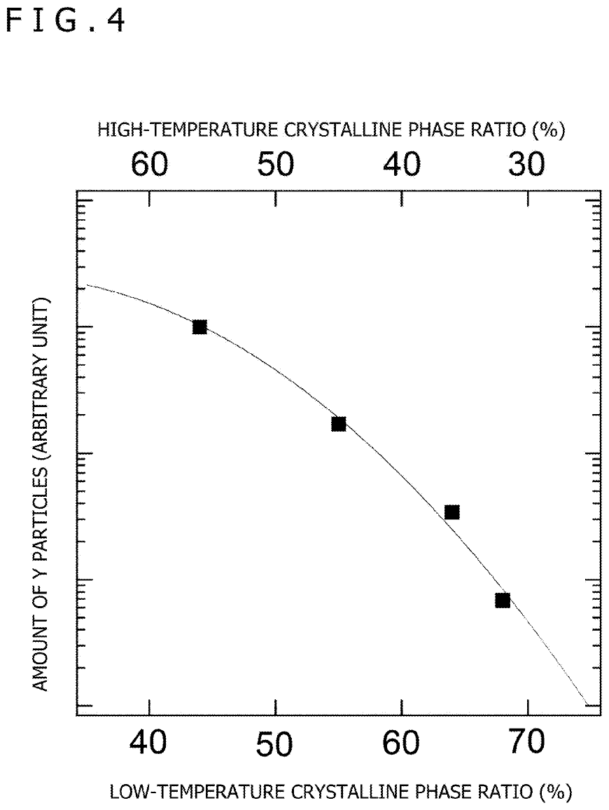

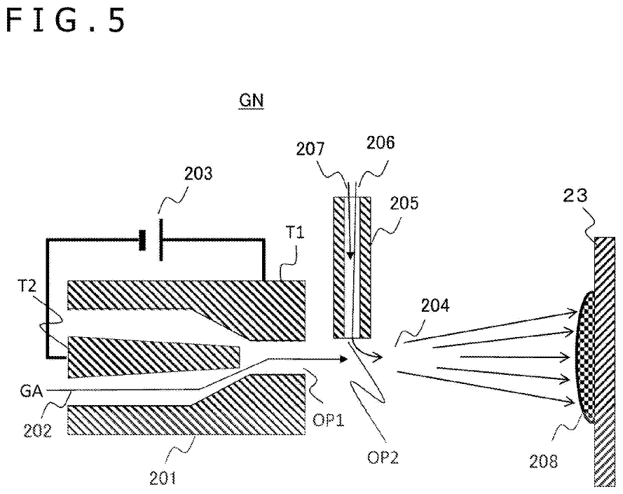

As depicted in FIG. 4 of Patent Document 9 (JP-2019-192701-A) or FIG. 5 of Advances in X-Ray Chemical Analysis 50, pp. 197 (2019) (Non-Patent Document 1), if an average crystallite size is increased, generation of particles in a semiconductor wafer in a plasma processing apparatus increases. On the basis of this, Patent Document 9 discloses a technology to suppress generation of particles by making the crystallite size of a coating equal to or smaller than 50 nm.

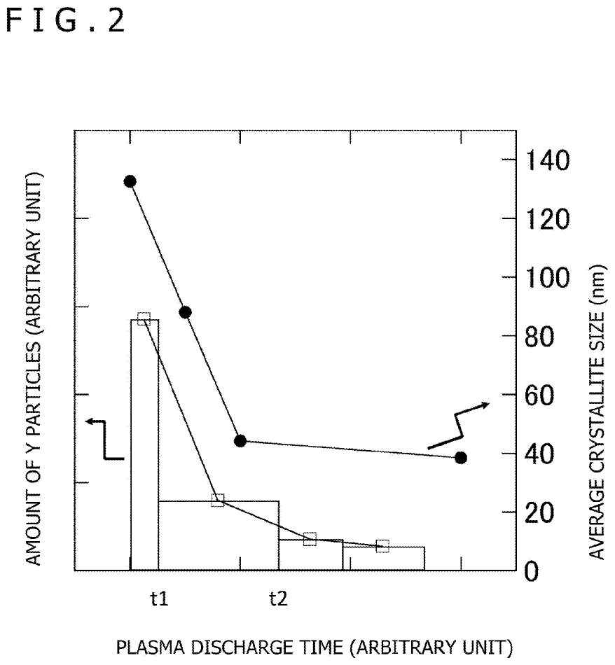

On the other hand, as depicted in FIG. 2, as the length of time of exposure to plasma discharge increases, the average crystallite size of a film decreases, and this decreases the amount of generated particles per unit time. However, it has been known that, once the crystallite size falls below 40 nm, the rate of the size decrease lowers. Furthermore, as depicted in FIG. 4 of Patent Document 9 and FIG. 5 of Non-Patent Document 1, even if the average crystallite size is reduced, the amount of generated particles does not become zero.

FIG. 2 is a figure depicting a correlation among plasma discharge time, the amount of generated particles, and crystallite sizes.

In FIG. 2, the bar chart depicts the amount of particles generated in a case where the film 24 is irradiated with plasma from a time (t1) at the left end of rods to a time (t2) on the right end of the rods. Furthermore, the amount of particles sensed per unit time is represented by white squares (□) along the left vertical axis in relation to the length of time during which the film 24 has been irradiated with the plasma represented by the horizontal axis (the middle of each length of irradiation time), and the average crystallite size of an inner wall material irradiated with the plasma is represented by black filled circles (●) along the right vertical axis.

As depicted in FIG. 2, it is known that, as the length of time of exposure to plasma discharge increases, the amount of generated particles per unit time decreases, and the average size of crystallites on the surface of the film 24 decreases. However, it is known that, when the average size falls below 40 nm, the rate of decrease of the average size of crystallites lowers.

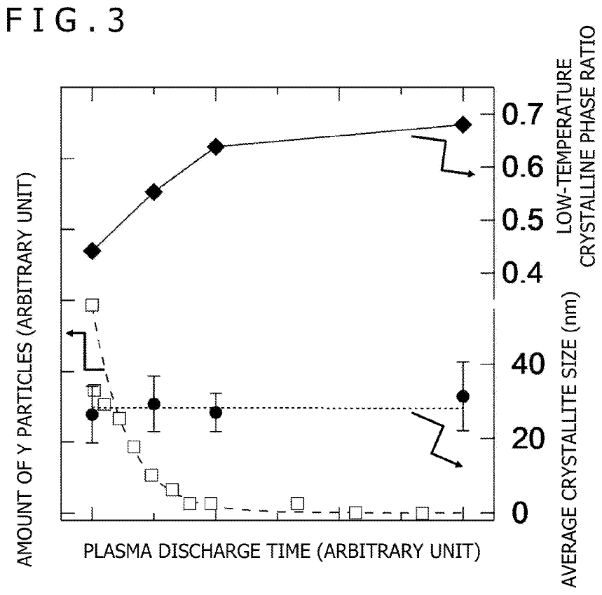

FIG. 3 depicts results of examination of a factor of generation of particles in the range of the average crystallite size equal to or smaller than 40 nm. Even if the length of time (horizontal axis) of exposure to the plasma is increased, the average crystallite size (the lower side of the right vertical axis) represented by black filled circles (●) does not represent significant changes when the average crystallite size is within a certain range centered on approximately 30 nm. On the other hand, the amount of generated particles per unit time (the amount of particles: left vertical axis) represented by open squares (□) decreases as the length of time of exposure to the plasma (horizontal axis) increases. At this time, the ratio of low-temperature crystalline phase (orthorhombic crystals) to the overall crystallites represented by filled rhombuses (♦) (low-temperature crystalline phase ratio: the upper side of the right vertical axis) increases. This low-temperature crystalline phase ratio is calculated as M1/(M1+M2), where M1 is the amount (number or mass or volume) of low-temperature crystallite phase (orthorhombic crystals), and M2 is the amount (number or mass or volume) of high-temperature crystalline phase (hexagonal crystals) in the material comprising the film 24.

It is considered from the results depicted in FIG. 2 and FIG. 3 that particles are not generated in a case where, in relation to changes in the length of time of exposure to plasma, the average crystallite size of the film 24 is equal to or smaller than 40 nm, and the ratio of hexagonal crystals does not change (the low-temperature crystalline phase ratio is a value between 0.6 and 0.7). On the basis of this, it is known that, in a case where the film 24 according to the present embodiment is used, several pieces of particles are generated as a result of accumulation of the length of time during which a plurality of the wafer 3 are processed by using plasma in the processing chamber 5. That is, the average size of crystals of the film 24 is better to be equal to or smaller than 50 nm.

The correlation between the amount of generated particles and high-temperature crystalline phases based on the results is depicted in FIG. 4. FIG. 4 is a figure depicting the correlation between the high-temperature crystalline phase ratio and the amount of particles generated with plasma discharge for a certain length of time. In FIG. 4, the horizontal axis represents the ratio of low-temperature crystalline phases or high-temperature crystalline phases of a material containing yttrium included in the film 24 on the surface of the grounded electrode 22 of the wafer 3 processed at the plasma processing apparatus 100 according to the present embodiment to the whole, and the vertical axis represents the amount of particles sensed from the surface of the wafer 3.

As depicted in FIG. 4, it is known that, as the low-temperature crystalline phase rate increases (the high-temperature crystalline phase ratio decreases), the amount of particles represented by filled squares (▪) decreases. On the basis of this, it is assumed that, by relatively lowering the high-temperature crystalline phase ratio of a material containing yttrium included in the film 24, it is possible to suppress generation of particles.

One typical conceivable means for reducing such high-temperature crystalline phases is to perform reheating and annealing to cause crystalline phase transition from remaining high-temperature crystalline phases to low-temperature crystalline phases. However, this means undesirably causes the growth of crystals of the material containing yttrium to proceed, resulting in size-increase of crystallites. Although an embodiment of Patent Document 1 discloses an example of a film whose ratio of orthorhombic crystals is 100%, crystal sizes of a material included in the film are equal to or greater than 1 μm.

On the other hand, Patent Document 9 discloses that, by maintaining the temperature of the surface of a film at a temperature in the range of temperatures equal to or higher than 280° C. or equal to or lower than 350° C. as described in an embodiment and figures of Patent Document 9 when the film is formed by a plasma spray method under an atmospheric pressure condition with use of a material containing an yttrium fluoride, it is possible to make the ratio of low-temperature phase (orthorhombic crystals) in crystals of the film equal to or higher than 60%, and to make crystallite sizes equal to or smaller than 50 nm. However, actually, it is difficult to realize a high ratio of low-temperature phase (orthorhombic crystal) that exceeds 70% for a material of a film containing yttrium.

The Y₂O₃—ZrO₂ solid solution disclosed in Patent Document 6 is zirconia to which yttria is added to stabilize high-temperature crystalline phases, and is a material which is well known as yttria stabilized zirconia. In addition, Non-Patent Document 2 discloses an academic research related to yttrium fluoride stabilized zirconia (YF₃—ZrO₂).

The present disclosers have assumed that a phase transition of high-temperature phase (hexagonal crystals) of a material included in the film 24 to low-temperature phase (orthorhombic crystals) occurs undesirably at a temperature in a particular range (e.g., a room temperature around 25° C.) and the phase transition of the crystals at this time generates fine particles or the like and have considered that generation of particles can be suppressed by suppressing such a phase transition to stabilize high-temperature crystalline phase crystals. That is, by stabilizing high-temperature crystalline phases to make it difficult for a crystalline phase transition from the high-temperature crystalline phases to low-temperature crystalline phases to occur at a time of plasma discharge, it can be expected to prevent generation of particles attributable to the crystalline phase transitions.

Non-Patent Document 3 derives, by a first principle molecular orbital method, that factors of stabilization of zirconia (ZrO₂) are a decrease of the coordination number of Zr due to the oxygen ion hole effect into which Y³⁺ ions with a valence smaller than the valence of Zr⁴⁺ ions are introduced and lattice strain into which ions with an ion radius greater than the ion radius (80 pm) of Zr⁴⁺ are introduced.

In addition, Patent Document 8 discloses a technology in which CaF₂ is added to an yttrium oxide and an yttrium fluoride and sintered and high-temperature crystalline phases of an yttrium oxyfluoride are stabilized or partially stabilized. This suggests that it is possible to stabilize high-temperature crystalline phases by introducing Ca²⁺ ions with a valence smaller than the valence of Y³⁺ and using the hole effects of fluorine ions or oxygen ions. Furthermore, Patent Document 7 discloses that high-temperature crystalline phases are partially stabilized, the mode of cracks changes, and cracks on a surface can be reduced by adding Y₂O₃ to an yttrium-based fluoride.

However, according to examination by the present disclosers, it is not possible with the element composition including Y, O, and F to stabilize high-temperature crystalline phases by the hole effect or lattice strain calculated with stabilization of zirconia. On the basis of this, it is considered that Y₂O₃—YF₃ in Patent Document 7 reduces cracks due to a factor which is different from stabilization or partial stabilization of high-temperature crystalline phase.

On the other hand, FIG. 1 of Non-Patent Document 4 discloses that 15 mol % of an yttrium oxide melts in an yttrium fluoride melt at 1260° C. According to examination by the present disclosers, it has been known that YF₃ is segregated in the grain boundaries of YOF particles in a fluorine-rich YOF film. This represents that Y₂O₃—YF₃ separates into YF₃ and YOF in the end, and the molar ratio YF₃:YOF becomes 3:2. On the basis of this, it is considered that Y₂O₃—YF₃ in Patent Document 7 stops the progress of cracks due to YOF in YF₃ serving as pinning sites.

According to examination by the present disclosers, results of analysis of the structures of crystals in the film 24 including an yttrium-based fluoride to which a very small amount of an yttrium oxide (Y₂O₃) is added by XRD (X-ray diffraction: X-ray Diffraction) represent that the main layer of the film 24 is a low-temperature crystalline phase (yttrium oxyfluoride (Y₅O₄F₇) and yttrium fluoride (YF₃)) and high-temperature crystalline phases (yttrium oxyfluoride (YOF) and yttrium fluoride (YF₃)) were included at the ratios of 40%. The crystallite size of Y₅O₄F₇ was 35 nm. In addition, results of measurement of the element concentrations of the film 24 using fluorescent X-rays were Y: 32 at %, O: 9.4 at %, and F: 58 at %.

As a result of analysis of the structures of crystals of the film 24 and sensing of concentrations of the film 24 exposed to plasma discharge for a long period of time, it could be known that the high-temperature crystalline phase YOF and the low-temperature crystalline phase YF₃ decreased, Y₅O₄F₇ increased, the element concentrations were Y: 35 at %, O: 14 at %, and F: 51 at %, and the oxygen concentration increased. This represents that the surface of the film 24 experienced a phase transition and also was oxidized. Cubic Y₂O₃ of the film 24 for which the added amount of Y₂O₃ was increased in order to increase the oxygen concentration was sensed by XRD, and its crystallite size was as large as 70 nm.

In view of this, the present disclosers further examined corrosion due to oxidation and fluoridization of the surface of the film 24 whose material is such YOF and Y₂O₃. Y₂O₃ on the surface of the film 24 is etched and also fluoridized by being exposed to plasma discharge during an etching process of the wafer 3. In addition, YF₃ in the film 24 is oxidized similarly.

That is, the film 24 having been exposed to plasma is a film of a mixture of YOF with a molar ratio Y₂O₃:YF₃ which is 1:1, and Y₅O₄F₇ which is a stabilized crystalline phase around YOF. Here, the surface of YOF also is oxidized if exposed to, for a long period of time, plasma discharge formed during the process on the wafer 3. On the basis of this, it is considered that, if the molar ratio Y:O of a material included in the film 24 formed by thermal spraying is 1:1.5 or higher, it is difficult for the surface to be oxidized even in a case where it is exposed to plasma for a long period of time. Furthermore, it is considered that, regarding F also, if the molar ratio Y:F of the material of the film 24 is 1:1 or higher, 1:1.4 or higher if possible, fluoridization in a case where the material is exposed to plasma is suppressed.

On the other hand, in Patent Document 8, Ca²⁺ ions with a valence smaller than the valence of Y³⁺ ions are introduced to YOF crystals by addition of CaF₂, in order to (at least partially) stabilize high-temperature crystalline phases of an yttrium oxyfluoride. Because of this, it is assumed that high-temperature crystalline phases are stabilized due to the oxygen or fluorine ions hole effect. However, generation of holes of oxygen ions or fluorine ions results in undesirable deterioration of the resistance against oxygen plasma or fluorine plasma.

In addition, regarding the concentrations of elements also, the concentration of fluorine increases, but the concentration of oxygen does not increase. Accordingly, even if the molar ratio Y:F becomes 1:1 or higher, the molar ratio Y:O does not become 1:1.5 or higher. Because of this, in a case where the film 24 formed by using a material containing YOF to which CaF₂ is added is exposed to plasma for a long period of time, oxidation of the surface of the film 24 may proceed undesirably, and particles may be generated.

In view of this, the present disclosers examined stabilization of the film 24 by the lattice strain effect by introducing ions with an ion radius greater than the ion radius (93 pm) of Y³⁺ to YOF crystals. Elements of ions with valences which are equal to or greater than two and with ion radii which are greater than 93 pm are limited to Ce³⁺ with an ion radius of 101 pm, Ca²⁺ with an ion radius of 99 pm, and Sr²⁺ with an ion radius of 113 pm.

By adding CeO₂, CaO₂, and SrO, it is possible to form the film 24 including, as a material, YOF whose crystals are (partially) stabilized. The film 24 can be formed by using an atmospheric plasma spraying (APS) method. The film 24 formed by using the atmospheric plasma spraying method can be formed as follows. While plasma is formed by using gas toward a covered base material in the atmospheric pressure or an air pressure close to it by using a CeO₂—YOF solid solution as a material, particles of the material of the film 24 are supplied to and melted in the plasma, and the particles are sprayed onto and stacked on the base material surface.

Atmospheric plasma spraying to be used for the formation of the film 24 is explained by using FIG. 5. FIG. 5 is a figure schematically depicting a manufacturing method for forming the film on the surface of the grounded electrode depicted in the embodiment in FIG. 1.

As depicted in FIG. 5, a gun GN for thermal spraying is arranged at a distance from the surface of the base material 23 which is a base material, and fine particles of a material of the film 24 are fed from the leading end of the gun GN toward formed plasma by using gas that is sprayed from the gun GN toward the top surface of the base material 23 to thereby make the fine particle melted or semi-melted, and spray the fine particles to the top surface of the base material 23 along the direction of the flow of the plasma.

The gun GN for thermal spraying includes a power supply 203, a nozzle 201, and a material supply pipe 205. The nozzle 201 is electrically connected to the power supply 203, and a predetermined voltage from the power supply 203 is applied to the nozzle 201. In addition, the nozzle 201 is formed to spray an argon (Ar) gas (GA) for plasma formation from an opening OP1 at its leading end. The material supply pipe 205 is arranged at a predetermined distance from the opening OP1 of the leading end of the nozzle 201. The material supply pipe 205 is formed to spray fine particles of a material from an opening OP2 at its leading end in a direction to cross a direction 202 of the flow of the argon gas GA.

Note that the nozzle 201 has a rod-like terminal T1 at its central portion and a cylindrical terminal T2 at its outer circumference surrounding the outer circumference of the terminal T1 with a clearance therebetween, and the terminal T1 and the terminal T2 are electrically connected to terminals with the respective polarities of the power supply 203. The clearance around the outer circumference of the terminal T1 at the central portion communicates with the opening OP1 of the gas spray port at the leading end of the nozzle 201, and forms a gas supply line of the argon gas GA. The direction of an axis extending from the gas supply line of the argon gas GA and passing through the opening OP1 of the gas spray port coincides with the direction of a spray of the argon gas GA from the leading end of the nozzle 201 or the direction of an emission of plasma formed ahead of the leading end of the nozzle 201.

Due to a high voltage applied from the power supply 203 to the respective terminals T1 and T2 of the nozzle 201, an arc discharge is generated in a space ahead of the spray port (OP1). In a state where the Ar gas GA supplied to the gas supply line from an undepicted gas source which is connected to the nozzle 201 is being released as the gas flow 202 from the gas spray port (OP1) toward the top surface of the base material 23, the high voltage is applied to the respective terminals T1 and T2 of the nozzle 201 from the power supply 203, and an arc discharge is generated in a space ahead of the spray port (OP1). The generated arc discharge excites the Ar gas, and thermal spray flames 204 are formed between the nozzle 201 and the base material 23. In this state, a thermal spray material 206 passes through the flow channel inside the material supply pipe 205 along with a transportation gas flow 207 in the material supply pipe 205, and is introduced (supplied) from the opening OP2 at the leading end of the material supply pipe 205 toward the thermal spray flames 204. In this embodiment, the thermal spray material 206 is fine particles of a material of the film 24 whose ratio between an yttrium oxyfluoride and CeO₂ has been adjusted such that CeO₂ is 35 mol % or a value that can be regarded as an approximation of 35 mol %.

Each particle included in the thermal spray material 206 becomes melted or semi-melted, and collides with and adheres to the surface of the base material 23 including a material containing aluminum or an aluminum alloy along the plasma of the thermal spray flames 204 and the flow 202 of the Ar gas GA. Then, each adhered particle included in the thermal spray material 206 is solidified on the surface of the base material 23 as it gets cooled. The particles that have been solidified and welded with each other cover a predetermined area on the surface of the base material 23, and also are stacked one on another until they form a desired thickness, thereby forming a coating 208 (24). This was repeated in this embodiment, and the film 24 with a thickness of approximately 100 μm was formed. In addition, the distance between the nozzle 201 and the base material 23 is set such that semi-melted particles are prevented from remaining inside the film 24 in a state where the coating 208 (24) with a desired thickness has been formed.

In any of examples explained below, the film 24 according to the embodiment is formed by using atmospheric plasma spraying depicted in FIG. 5. Note that, in the example described above, the amounts of CeO₂, CaO₂, and SrO need to be increased in order to make the molar ratio (concentration) of oxygen equal to or higher than 150% of the molar ratio of Y (yttrium) for enhancement of the resistance against oxygen and fluorine in the plasma. However, Ca and Sr may undesirably contaminate a semiconductor wafer since they become divalent positive ions, and it is not appropriate to excessively increase the added amounts.

The concentration of each element of the thus-formed film 24 was measured by use of fluorescent X-rays. As a result, the concentration of each element on the surface of the film 24 is as follows: Y: 20 at %, O: 45 at %, F: 22 at %, and Ce: 13 at %. In addition, it was sensed that Y:O was 1:2.2 and Y:F was 1:1.1.

It was known from results of analysis of the structures of crystals by XRD that the main layer was YOF (CeO₂—YOF solid solution), and there were very small amounts of YF₃ and CeO₂ crystals. In addition, the crystallite size of YOF was 40 nm, and the hexagonal crystal ratio of the CeO₂—YOF solid solution was approximately 90%. On the other hand, as a result of analysis of the structures of crystals of the film 24 exposed to the plasma for a long period of time, almost no changes in the crystalline phase ratio of hexagonal crystals were acknowledged as compared to one which was not exposed to the plasma.

Although the high-temperature crystalline phase and low-temperature crystalline phase of an yttrium oxyfluoride are hexagonal crystals and orthorhombic crystals, respectively, since it is not clear whether hexagonal crystals can be regarded as the high-temperature crystalline phase in a case where they are stabilized, they are described not as the high-temperature crystalline phase or the low-temperature crystalline phase, but as hexagonal crystals or orthorhombic crystals.

The yttrium oxyfluoride described above includes Y³⁺, O²⁻, and F⁻. Y₅O₆F₃ or the like which is obtained by relacing 2F⁻ and O²⁻ may be used in order to increase the concentration (molar ratio) of oxygen in the film 24, but it is not possible to increase the concentrations of both O and F relative to Y since Y³⁺ is the only positive ions. In view of this, the present disclosers examined a method for increasing the oxygen concentration by adding positive ions of an element other than Y.

As stable structures including YOF and an additional element, YFSeO₃, YFCO₃, YFSO₄, YFMoO₄, YF(OH)₂, and the like were examined. The ion radii of the elements added to these materials are Se⁶⁺: 42 pm, C⁴⁺: 15 pm, S⁶⁺: 29 pm, and Mo⁶⁺: 62 pm, which are smaller than the ion radius (93 pm) of Y³⁺.

If positive ions whose ion radius is smaller than the ion radius of Y³⁺ and whose valence is greater than the valence of Y³⁺ is added to an yttrium oxyfluoride, there are excess electrons. Oxygen is attached to them, and this makes the coordination numbers match. Although the ion radii of the added elements are smaller than the ion radius of Y³⁺, it is considered that lattice strain is generated when two to three oxygen ions (ion radius of 14 pm) bind to the additional elements, and the structures can be stabilized.

In addition, in YF(OH)₂, hydrogen ions and oxygen ions bind with each other to form (OH)⁻, and there are two oxygen ions with the ion radius of 14 pm (the size of one proton is ignored). Accordingly, lattice strain is generated, and the structure is stabilized. This suggests that it is possible to attempt to introduce divalent anions with a lot of oxygen into an oxygen site, and stabilize the structure by the lattice strain effect, by adding a compound including Y, O, and F including an element M to be positive ions with an ion radius equal to or smaller than the ion radius of Y³⁺.

In view of this, the present disclosers examined whether it is possible to make the oxygen concentration equal to or higher than 150% of Y, make the fluorine concentration equal to or higher than 100% of Y, and obtain high resistance against fluorine or oxygen in plasma by adding the element M to be positive ions with an ion radius equal to or smaller than the ion radius of Y³⁺ to a YOF material.

The element M needs to be +4 valence or +6 valence ions, and have an ion radius smaller than the ion radius of Y³⁺. In this case, candidates are C⁴⁺, Si⁴⁺, Ge⁴⁺, Zr⁴⁺, Hf⁴⁺, S⁶⁺, Cr⁶⁺, Se⁶⁺, Mo⁶⁺, Te⁶⁺, and W⁶⁺. Sn and Pb were excluded since they have divalent ion radii which are greater than the ion radius of Y³⁺. In addition, elements to be monovalent or divalent ions were excluded from candidates of the element M since they are likely to be elements to cause semiconductor contamination. That is, the element M to be +4 valence or +6 valence ions is at least any one of C, Si, Ge, Zr, Hf, S, Cr, Se, Mo, Te, and W.

By thermal spraying of, as a material, an yttrium oxyfluoride, such an element M and oxides of Y and F, the film 24 according to the present embodiment was formed by using atmospheric plasma similarly to the examination described above. That is, in the present example, particles of a material containing particles of YFCO₃ including the yttrium oxyfluoride and C (carbon) as the element M were introduced along with transportation gas to thermal spray flames formed by causing a discharge while a high voltage was being applied to the nozzle, and the argon gas was being caused to flow as plasma gas, and melted particles were emitted to the surface of the base material of the grounded electrode 22 to form the film 24.

Results of sensing of the concentrations of the elements in such a film 24 by using fluorescent X-rays represent that Y: 22 at %, O: 45 at %, F: 22 at %, and C: 11 at % and that Y:O was 1:2 and Y:F was 1:1. Furthermore, results of analysis of the structures of crystals by XRD represent that crystals of YOF and Y(CO₃)F were mixedly present on the surface of the film 24. The crystallite size of YOF was 28 nm, and the ratio of hexagonal crystals was approximately almost 100%.

Furthermore, as a result of analysis and comparison of crystal structures between the film 24 after exposure to the plasma for a long period of time and the film 24 before the exposure, significant changes were not acknowledged in the phase ratio of hexagonal crystals even after the exposure. Furthermore, similarly, significant changes were not acknowledged also in the molar ratio (concentration) of oxygen in the film 24. Since the added element M is carbon in the present example, it is assumed that the influence of the addition on processes of manufacturing semiconductor devices is sufficiently small.

Next, the film 24 was formed by using YFSO₄ whose element M as a material added to an yttrium oxyfluoride was S. Similarly, as a result of sensing of the concentrations of elements by fluorescent X-ray measurement, it was sensed that Y: 25 at %, O: 42 at %, F: 25 at %, and S: 7.5 at % and that Y:O was 1:1.7 and Y:F was 1:1. Similarly, as a result of analysis of crystalline structures by XRD, it could be known that the main layer was YOF, a very small amount of YFSO₄ was present, the crystallite size of YOF was 40 nm, and the ratio of hexagonal crystals to the whole was approximately 90%. Furthermore, significant changes were acknowledged neither in the phase ratio of hexagonal crystals nor in the concentration of oxygen in the film 24 even after exposure to the plasma for a long period of time as compared to the film 24 before the exposure.

The film 24 can be formed similarly also by using YFSeO₃ or YFMoO₄ using Se or Mo as the element M, other than YFCO₃ and YFSO₄ described above. As another embodiment of such a film 24, the film 24 may be formed by using a suspension plasma spray method.

In the thermal spraying method, similarly to the example depicted in FIG. 5, a material which is a suspension of particles of a material containing particles of an yttrium oxyfluoride and YFMoO₄ in a solvent was introduced, along with the solvent, to the thermal spray flames 204 generated by applying a high voltage to the terminals at the middle portion and outer circumference of the nozzle 201 under a condition of the atmospheric pressure to induce an arc discharge, and turning the supplied Ar gas into plasma, and the material was emitted to the surface of the base material 23 of the grounded electrode 22, and caused to adhere onto and cover the surface, thereby forming the film 24. In the present example, the thermal spray flames 204 volatilizes the solvent by heat, the temperature of the thermal spraying was set high such that the particles of the thermal spray material 206 are prevented from remaining in the film 24 in a semi-melted state, and the distance between a nozzle 203 and the top surface of the base material 23 was set to a value in a predetermined range. As materials to form the film 24, an yttrium oxyfluoride and YFCO₃, YFSO₄, or YFSeO₃ may be used.

The concentrations of elements of the film 24 sensed in a manner similar to the manner described above were Y: 20 at %, O: 50 at %, F: 20 at %, and Mo: 10 at %, Y:O was 1:2.5, and Y:F was 1:1. Regarding the structures of crystals, it could be known that the main layer was YOF, the crystallite size of YOF was 33 nm, the ratio of hexagonal crystals was approximately 70%, and significant changes were not acknowledged in the phase ratio of hexagonal crystals even in a case where the film 24 was exposed to plasma for a long period of time.

In a case where the film 24 is formed by using a suspension plasma spray method, as another thermal spray material, a suspension of particles of an yttrium oxyfluoride or an yttrium fluoride and powders of silicon dioxide in a solvent can be used. It could be confirmed that the concentrations of elements of the thus-formed film 24 were Y: 20 at %, O: 40 at %, F: 28 at %, and Si: 12 at % and that Y:O was 1:2, and Y:F was 1:1.4. In addition, as a result of similar analysis of the structures of crystals, it was known that the main layer of the film 24 was Y₅O₄F₇, and YOF also was included (it is considered that it was SiO₂—Y₅O₄F₇ or SiO₂—YOF).

In addition, the crystallite size of Y₅O₄F₇ was 30 nm, the rate of hexagonal crystals was approximately 80%, and significant changes were not acknowledged in the phase ratio of hexagonal crystals even after exposure to the plasma for a long period of time. Other than a silicon oxide, a germanium oxide, a hafnium oxide, a sulfur oxide, a selenium oxide, a chromium oxide, a molybdenum oxide, a tellurium oxide, or a tungsten oxide also can be used.

Furthermore, as another embodiment, the film 24 was formed by using PVD. The target of PVD was a sintered material of an yttrium oxyfluoride, a chip of an yttria stabilized zirconia was placed thereon, and the film was formed.

In this example, it could be known that the concentrations of elements of the film 24 were Y: 25 at %, O: 42 at %, F: 28 at %, and Zr: 5 at % and that Y:O was 1:1.7 and Y:F was 1:1.1. Results of analysis of the structures of crystals by XRD represent that the main layer of the film 24 was Y₅O₄F₇, and Y₂O₃ and ZrO₂ were not sensed. The crystallite size of Y₅O₄F₇ was 40 nm, and the ratio of hexagonal crystals was approximately 25%. Significant changes were not sensed in the phase ratio of hexagonal crystals and orthorhombic crystals (and/or tetragonal crystals) in a case where the film 24 was exposed to plasma for a long period of time as compared to the film 24 before the exposure.

Similarly, the film 24 was formed by using, as the target of PVD, a compression-molded mixture of fine powders of a sintered material of an yttrium oxyfluoride obtained by pulverization, and fine powders of YFCO₃ obtained by pulverization. Instead of YFCO₃, YFSeO₃, YFSO₄, or YFMoO₄ can be used.

It was sensed that the concentrations of elements of the thus-formed film 24 in this case were Y: 25 at %, O: 50 at %, F: 25 at %, and C: 25 at % and that Y:O was 1:2 and Y:F was 1:1. In addition, as a result of analysis of the structures of crystals by XRD, it could be known that the film 24 is a mixture of crystals of YOF and Y(CO₃)F, the crystallite size of YOF was 38 nm, and the ratio of hexagonal crystals was approximately 100%. In addition, significant changes were not acknowledged in the phase ratio of hexagonal crystals even in a case where the film 24 was exposed to plasma for a long period of time as compared to the film 24 before the exposure.

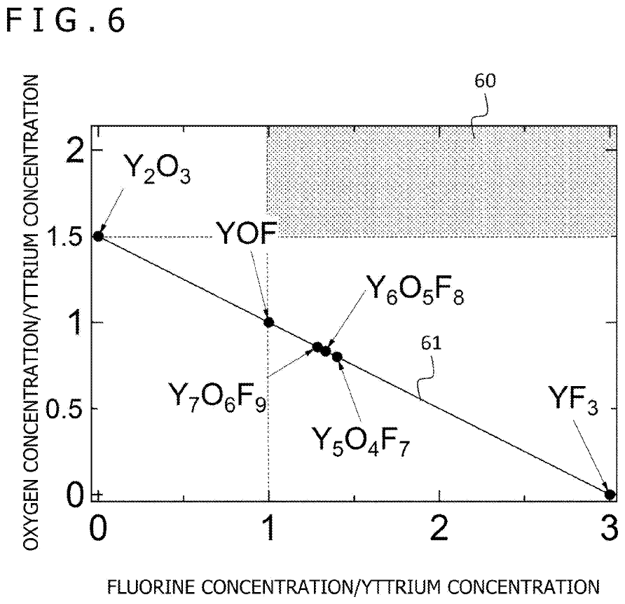

FIG. 6 depicts a relation among the compositions of yttrium oxyfluorides, an yttrium fluoride, and an yttrium oxide. Ternary forms, Y—O—F, are present only on the line from Y:O=1:1.5 to Y:F=1:3. Since yttrium is a +3 valence element, oxygen atoms are an element of −2 valence ions, and fluorine is a −1 valence element, Y—O—F cannot deviate from the line without the positive-valence element M other than yttrium. The range of the present embodiment lies in a shaded portion 60, and it cannot be realized with only the yttrium oxyfluorides, the yttrium fluoride, and the yttrium oxide which correspond to the conventional technologies.

Crystals of Y₂O₃ are not oxidized even if oxygen plasma processing is performed. This is because an amount of oxygen that exceeds 150% of yttrium cannot bind chemically. In order for an amount of oxygen that exceeds 150% of yttrium to bind, the presence of the positive-valence element M is essential. In addition, if fluorine plasma processing is performed on crystals of Y₂O₃, they become YOF to Y₅O₄F₇ whose Y:F ratios are in the range of 1:1 to 1:1.4. At this time, the Y:O ratios are 1:1 to 1:0.8. Although oxygen is removed, and YF₃ is produced in some cases if a hydrogen reduction process accompanies as in HF gas plasma processing, since 0 decreases as F increases as can be known from FIG. 6, it is not possible to pursue both molar ratios Y:O≥1:1.5 and Y:F≥1:1.

An inner wall material which is typically called an YOF film is a material of Y₂O₃, YF₃, Y₅O₄F₇, Y₆O₅F₈, or Y₆O₆F₉, or a mixture of these. Since all of these are materials that are present on the line segment 61 depicted in FIG. 6, the average molar ratio of overall YOF which is a material to be obtained does deviate from the line segment 61 in FIG. 6 no matter at which ratios these materials are mixed. Accordingly, no matter whether a process performed on the wafer 3 in the processing chamber 5 uses plasma generated by using a gas containing oxygen or plasma generated by using a gas containing fluorine, the composition of YOF of a material included in the film 24 on the surface of the grounded electrode 22 is present on the line segment 61 in FIG. 6.

According to examination of the composition of the film 24 performed under a plurality of conditions by the present disclosers, there were cases where the composition slightly deviated from the line segment 61 apparently, but it was determined that they are caused by the influence of by-products of a process using plasma (e.g., one formed due to binding of F or O to Cl that remained after a process with plasma generated by using a Cl₂ gas, etc.), and it was determined that compositions of YOF that were included in the film 24 before the process were on the line segment 61 in FIG. 6. That is, it is considered that the material containing three elements, Y—O—F, of the film 24 itself was on the line segment 61 in FIG. 6 in terms of changes in the composition that accompany changes caused by exposure to the plasma, but due to the influence of reaction products or the like that accompany processes on the wafer 3, the material of the film 24 does not become one on the line segment 61 in FIG. 6 in some cases.

In the present embodiment, by adding the element M to an inner wall material, the concentration ratio between oxygen and fluorine in an inner wall material was changed from ones on the line segment 61 in FIG. 6 to ones in the shaded portion 60, the oxygen concentration and the fluorine concentration are made higher than those of a YOF inner wall material, reactions of the inner wall material with radical oxygen or radical fluorine is suppressed by using oxygen plasma or fluorine plasma, and the plasma resistance is enhanced.

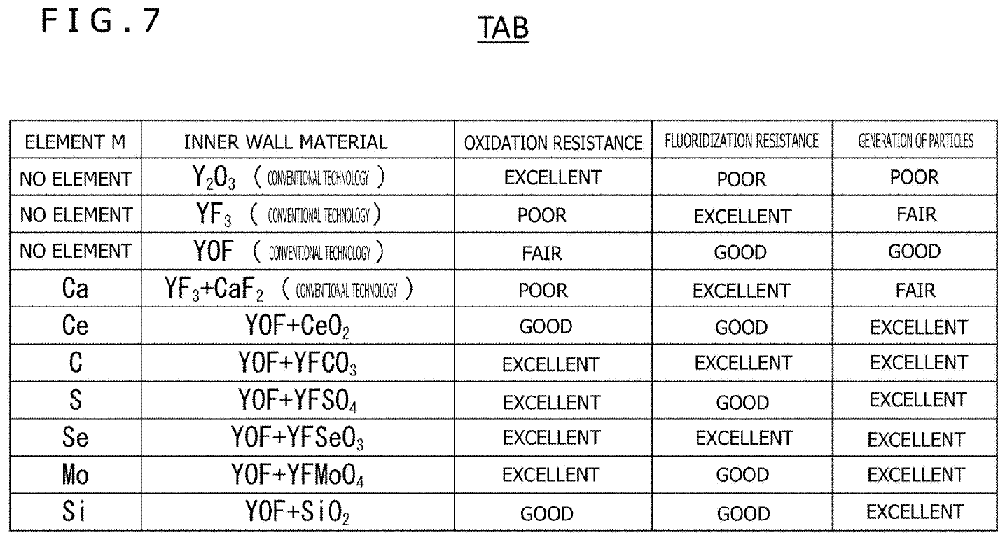

FIG. 7 is a figure depicting a table depicting comparison of characteristics among films formed according to the conventional technologies and the film 24 according to the present embodiment. A table TAB depicted in FIG. 7 indicates qualitative superiority/inferiority of characteristics with four levels (Excellent, Good, Fair, and Poor) regarding the films formed according to the conventional technologies and the film 24 according to the present embodiment. In the case depicted in FIG. 7, as representative examples, the film 24 according to the present embodiment includes, as a material of the inner wall material, a material containing an yttrium oxyfluoride (YOF), and an oxide, a fluoride, or an oxyfluoride (CeO₂, YFCO₃, YFSO₄, YFSeO₃, YFMoO₄, or SiO₂) of the element M to be +4 valence or +6 valence ions (at least any one of C, Si, Ge, Zr, Hf, S, Cr, Se, Mo, Te, and W).

The films according to the conventional technologies correspond to portions whose element M is “no element,” “no element,” “no element,” and Ca, and whose inner wall material is Y₂O₃, YF₃, YOF, and YF₃+CaF₃. In addition, the film 24 according to the present embodiment corresponds to portions whose element M is Ce, C, S, Se, Mo, and Si, and whose inner wall material is YOF+CeO₂, YOF+YFCO₃, YOF+YFSO₄, YOF+YFSeO₃, YOF+YFMoO₄, and YOF+SiO₂. As depicted in FIG. 7, the film 24 according to the present embodiment has respective characteristics regarding oxidize characteristics, fluoridization resistance, and generation of particles which are represented by Excellent or Good, and it can be considered that they have excellent characteristics as compared with the respective characteristics of the films according to the conventional technologies.

Stated differently, the film 24 is a film including a material containing at least one of an yttrium oxide, an yttrium fluoride, and an yttrium oxyfluoride, and an element to be +4 valence or +6 valence ions whose ion radius is smaller than an ion radius of +3 valence yttrium ions, the film including the material containing oxygen at a molar ratio which is equal to or higher than 150% of yttrium and fluorine at a molar ratio which is equal to or higher than 100%, preferably equal to or higher than 140%, of yttrium, on average.

In addition, the material of the inner wall material included in the film 24 is a material containing at least one of an yttrium oxide, an yttrium fluoride, and an yttrium oxyfluoride, and an oxide, a fluoride, or an oxyfluoride of the element M to be +4 valence or +6 valence ions. The yttrium oxide, the yttrium fluoride or the yttrium oxyfluoride is at least one of Y₂O₃, YF₃, YOF, and Y₅O₄F₇. In addition, the oxide, the fluoride, or the oxyfluoride of the element M to be +4 valence or +6 valence ions is any one of YFCO₃, YFSeO₃, YFSO₄, and YFMoO₄. Then, generation of particles is suppressed by making the average of crystallite sizes (the sizes of crystals) of the film 24 equal to or smaller than 50 nm.

Whereas the disclosure made by the present disclosers has been explained specifically on the basis of an embodiment thus far, it is needless to say that the present disclosure is not limited to the embodiment described above, but can be modified variously.

### INDUSTRIAL APPLICABILITY

The present disclosure can be applied to a plasma processing apparatus that processes a processing-subject sample such as a semiconductor wafer, an inner member of the plasma processing apparatus, and a method of manufacturing an inner member of a plasma processing apparatus.

### DESCRIPTION OF REFERENCE NUMERALS

1: Shower plate
2: Window member
3: Wafer
4: Stage
5: Processing chamber
6: Clearance
7: Through hole
8: Evacuation pipe
9: Dry pump
10: Turbomolecular pump
11: Impedance matching device
12: High frequency power supply
13: Plasma
14: Pressure adjustment plate
15: Valve
16: Valve
17: Valve
18: Magnetron oscillator
19: Waveguide
20: Solenoid coil
21: Solenoid coil
22: Grounded electrode
23: Base material
24: Coating
25: Process gas supply pipe
26: Valve
27: High vacuum pressure sensor
201: Nozzle
202: Gas flow
203: Power supply
204: Thermal spray flames
205: Material supply pipe
206: Thermal spray material
207: Transportation gas flow

1. A plasma processing apparatus comprising:
a processing chamber that is arranged inside a vacuum vessel and in which plasma is formed; and
a member that is arranged in the processing chamber and has a surface that faces the plasma, wherein
the member includes, on a surface thereof, a film including a material containing at least one of an yttrium oxide, an yttrium fluoride, and an yttrium oxyfluoride, and an element to be +4 valence or +6 valence ions whose ion radius is smaller than an ion radius of +3 valence yttrium ions, the film including the material containing oxygen at a molar ratio which is equal to or higher than 150% of yttrium, and fluorine at a molar ratio which is equal to or higher than 100%, preferably equal to or higher than 140%, of yttrium, on average.

2. The plasma processing apparatus according to claim 1, wherein
the element to be the +4 valence or +6 valence ions is at least any one of C, Si, Ge, Zr, Hf, S, Cr, Se, Mo, Te, and W.

3. The plasma processing apparatus according to claim 1 or 2, wherein
the film is formed by thermal spraying of a material containing at least one of the yttrium oxide, the yttrium fluoride, and the yttrium oxyfluoride, and an oxide, a fluoride, or an oxyfluoride of the element to be the +4 valence or +6 valence ions.

4. The plasma processing apparatus according to claim 3, wherein
the yttrium oxide, the yttrium fluoride, or the yttrium oxyfluoride includes at least one of Y₂O₃, YF₃, YOF, and Y₅O₄F₇, and the oxide, the fluoride, or the oxyfluoride of the element to be the +4 valence or +6 valence ions includes any one of YFCO₃, YFSeO₃, YFSO₄, and YFMoO₄.

5. The plasma processing apparatus according to claim 1 or 2, wherein
an average size of crystals of the film is equal to or smaller than 50 nm.

6. An inner member of a plasma processing apparatus having a processing chamber that is arranged inside a vacuum vessel and in which plasma is formed, the inner member being arranged inside the processing chamber, and having a surface that faces the plasma, wherein
the inner member includes, on a surface thereof, a film including a material containing at least one of an yttrium oxide, an yttrium fluoride, and an yttrium oxyfluoride, and an element to be +4 valence or +6 valence ions whose ion radius is smaller than an ion radius of +3 valence yttrium ions, the film including the material containing oxygen at a molar ratio which is equal to or higher than 150% of yttrium, and fluorine at a molar ratio which is equal to or higher than 100%, preferably equal to or higher than 140%, of yttrium, on average.

7. The inner member of the plasma processing apparatus according to claim 6, wherein
the element to be the +4 valence or +6 valence ions is at least any one of C, Si, Ge, Zr, Hf, S, Cr, Se, Mo, Te, and W.

8. The inner member of the plasma processing apparatus according to claim 6 or 7, wherein
the film is formed by thermal spraying of a material containing at least one of the yttrium oxide, the yttrium fluoride, and the yttrium oxyfluoride, and an oxide, a fluoride, or an oxyfluoride of the element to be the +4 valence or +6 valence ions.

9. The inner member of the plasma processing apparatus according to claim 8, wherein
the yttrium oxide, the yttrium fluoride, or the yttrium oxyfluoride includes at least one of Y₂O₃, YF₃, YOF, and Y₅O₄F₇, and the oxide, the fluoride, or the oxyfluoride of the element to be the +4 valence or +6 valence ions includes any one of YFCO₃, YFSeO₃, YFSO₄, and YFMoO₄.

10. The inner member of the plasma processing apparatus according to claim 6 or 7, wherein
an average size of crystals of the film is equal to or smaller than 50 nm.

11. A method of manufacturing an inner member of a plasma processing apparatus, the inner member being arranged in a processing chamber that is arranged inside a vacuum vessel and in which plasma is formed, and having a surface that faces the plasma, the method comprising:
forming, on the surface of the inner member, a film including a material containing oxygen at a molar ratio which is equal to or higher than 150% of yttrium, and fluorine at a molar ratio which is equal to or higher than 100%, preferably equal to or higher than 140%, of yttrium, on average, by performing, at an atmospheric pressure and by using plasma, thermal spraying of the material containing at least one of an yttrium oxide, an yttrium fluoride, and an yttrium oxyfluoride, and an element to be +4 valence or +6 valence ions whose ion radius is smaller than an ion radius of +3 valence yttrium ions.

12. The method of manufacturing an inner member of a plasma processing apparatus according to claim 11, wherein
the element to be the +4 valence or +6 valence ions is at least any one of C, Si, Ge, Zr, Hf, S, Cr, Se, Mo, Te, and W.

13. The method of manufacturing an inner member of a plasma processing apparatus according to claim 11 or 12, wherein
the film is formed by thermal spraying of a material containing at least one of the yttrium oxide, the yttrium fluoride, and the yttrium oxyfluoride, and an oxide, a fluoride, or an oxyfluoride of the element to be the +4 valence or +6 valence ions.

14. The method of manufacturing an inner member of a plasma processing apparatus according to claim 13, wherein
the yttrium oxide, the yttrium fluoride, or the yttrium oxyfluoride includes at least one of Y₂O₃, YF₃, YOF, and Y₅O₄F₇, and the oxide, the fluoride, or the oxyfluoride of the element to be the +4 valence or +6 valence ions includes any one of YFCO₃, YFSeO₃, YESO₄, and YFMoO₄.

15. The method of manufacturing an inner member of a plasma processing apparatus according to claim 11 or 12, wherein
an average size of crystals of the film is equal to or smaller than 50 nm.
